(19) United States
(12) Patent Application Publication
(10) Pub. No.: US 2025/0323618 A1
(43) Pub. Date: Oct. 16, 2025

(54) ACOUSTIC WAVE DEVICE, METHOD OF MANUFACTURING THE SAME, AND MODULE

(71) Applicant: Murata Manufacturing Co., Ltd., Nagaokakyo-shi (JP)

(72) Inventors: Tetsuya ODA, Nagaokakyo-shi (JP); Toru KOMATSU, Nagaokakyo-shi (JP); Tadashi NOMURA, Nagaokakyo-shi (JP)

(21) Appl. No.: 19/248,939

(22) Filed: Jun. 25, 2025

Related U.S. Application Data
(63) Continuation of application No. PCT/JP2023/045608, filed on Dec. 20, 2023.

(30) Foreign Application Priority Data
Dec. 27, 2022 (JP) 2022-210480

(51) Int. Cl. H03H 9/02; H03H 3/08; H03H 9/05

(52) U.S. Cl. CPC H03H 9/02913; H03H 3/08; H03H 9/02086; H03H 9/0514; H03H 9/0533; H03H 9/059

(57) ABSTRACT

An acoustic wave device that can correctly perform an operation as the acoustic wave device and can achieve suppression of internal noise interference, a method of manufacturing the same, and a module are provided. The acoustic wave device includes a base member provided with a plurality of side surfaces, a ground pad wire, and a first shield film that covers the plurality of side surfaces. Since the ground pad wire and the first shield film are electrically connected to each other, operation as the acoustic wave device can correctly be performed and internal noise interference can be suppressed.

### CROSS REFERENCE TO RELATED APPLICATION

This is a continuation of International Application No. PCT/JP2023/045608 filed on Dec. 20, 2023 which claims priority from Japanese Patent Application No. 2022-210480 filed on Dec. 27, 2022. The contents of these applications are incorporated herein by reference in their entireties.

### BACKGROUND OF THE DISCLOSURE

### Field of the Disclosure

The present disclosure relates to an acoustic wave device, a method of manufacturing the same, and a module.

### Description of the Related Art

With increase in number of components in an electronic device such as a smartphone in recent years and with reduction in size and lowering in profile of the electronic device, noise interference between electronic components that are used gives rise to a problem. In order to suppress noise interference, adoption of an EMI shield film in a modular product for communication has been demanded.

U.S. Pat. No. 10,804,217B2 discloses a semiconductor device including an EMI shield structure. This semiconductor device includes an insulating substrate and a semiconductor die mounted on an upper surface of the insulating substrate. The semiconductor die and the upper surface of the insulating substrate are sealed with sealing resin. An upper surface of the semiconductor die is exposed through the sealing resin. A side surface of the semiconductor die is covered with a first shield film. The upper surface of the semiconductor die and the upper surface and the side surface of the sealing resin are covered with a second shield film.

### BRIEF SUMMARY OF THE DISCLOSURE

As described above, the semiconductor die provided with the first shield film on the side surface may be contained in a module. In order to connect the first shield film to a GND potential, the upper surface of the semiconductor die is exposed through the upper surface of the sealing resin and the first shield film is electrically connected to the second shield film that covers an upper surface and a side surface of the entire module. In an example where this semiconductor die is, for example, a wafer-level surface acoustic wave (WL-SAW) filter, a wire for plating power feed may be exposed at the side surface of the die. When this wire is exposed at the side surface, the wire tends to electrically be connected to the first shield film. This wire is finally used for both of a ground (GND) application and a signal application. Therefore, when the first shield film is connected to the GND potential, a wire for the signal is also connected to the GND potential and the semiconductor die does not operate as a surface acoustic wave (SAW filter).

In addition, while the first shield film that covers the side surface of the semiconductor die is not connected to the GND potential, an effect of suppression of noise interference between electronic components becomes lower.

Then, a possible benefit of the present disclosure is to provide an acoustic wave device that can correctly perform an operation as the acoustic wave device and can achieve suppression of internal noise interference, a method of manufacturing the same, and a module.

In order to achieve the possible benefit, an acoustic wave device based on the present disclosure includes a base member provided with a first surface and a second surface and a plurality of side surfaces, the first surface and the second surface defining front and rear surfaces, the plurality of side surfaces connecting the first surface and the second surface to each other, a resonator arranged at the first surface, a signal pad and a ground pad arranged at the first surface, a signal pad wire that extends to connect the signal pad and an end of the first surface to each other at the first surface, a ground pad wire that extends to connect the ground pad and an end of the first surface to each other at the first surface, a support layer arranged at the first surface to surround the resonator, a cover layer connected to the first surface with the support layer being interposed, the cover layer covering the resonator, a plurality of conductor vias electrically connected to the signal pad and the ground pad, the plurality of conductor vias passing through the support layer and the cover layer, the plurality of conductor vias being exposed at a surface of the cover layer opposite to the base member, and a first shield film that covers the plurality of side surfaces. The ground pad wire is electrically connected to the first shield film at the end of the first surface.

According to the present disclosure, since the ground pad wire and the first shield film that covers the side surfaces are electrically connected to each other, operation as the acoustic wave device can correctly be performed and internal noise interference can be suppressed.

### BRIEF DESCRIPTION OF THE SEVERAL VIEWS OF THE DRAWINGS

FIG. 1 is a first perspective view of an acoustic wave device in a first embodiment based on the present disclosure.

FIG. 2 is a second perspective view of the acoustic wave device in the first embodiment based on the present disclosure.

FIG. 3 is a plan view of the acoustic wave device in the first embodiment based on the present disclosure.

FIG. 4 is a bottom view with bumps and a cover layer of the acoustic wave device in the first embodiment based on the present disclosure having been removed.

FIG. 5 is a cross-sectional view along the line V-V in FIG. 3.

FIG. 6 is a cross-sectional view along the line VI-VI in FIG. 3.

FIG. 7 is a partial cross-sectional view of the acoustic wave device in the first embodiment based on the present disclosure.

FIG. 8 is an enlarged view of a Z portion in FIG. 7.

FIG. 9 is an illustrative view of areas corresponding to four acoustic wave devices in a substrate assembly used for manufacturing the acoustic wave device in the first embodiment based on the present disclosure.

FIG. 10 is a first illustrative view of a method of manufacturing an acoustic wave device in a second embodiment based on the present disclosure.

FIG. 11 is a second illustrative view of the method of manufacturing an acoustic wave device in the second embodiment based on the present disclosure.

FIG. 12 is a third illustrative view of the method of manufacturing an acoustic wave device in the second embodiment based on the present disclosure.

FIG. 13 is a fourth illustrative view of the method of manufacturing an acoustic wave device in the second embodiment based on the present disclosure.

FIG. 14 is a fifth illustrative view of the method of manufacturing an acoustic wave device in the second embodiment based on the present disclosure.

FIG. 15 is a sixth illustrative view of the method of manufacturing an acoustic wave device in the second embodiment based on the present disclosure.

FIG. 16 is a seventh illustrative view of the method of manufacturing an acoustic wave device in the second embodiment based on the present disclosure.

FIG. 17 is an eighth illustrative view of the method of manufacturing an acoustic wave device in the second embodiment based on the present disclosure.

FIG. 18 is a ninth illustrative view of the method of manufacturing an acoustic wave device in the second embodiment based on the present disclosure.

FIG. 19 is a tenth illustrative view of the method of manufacturing an acoustic wave device in the second embodiment based on the present disclosure.

FIG. 20 is an eleventh illustrative view of the method of manufacturing an acoustic wave device in the second embodiment based on the present disclosure.

FIG. 21 is a twelfth illustrative view of the method of manufacturing an acoustic wave device in the second embodiment based on the present disclosure.

FIG. 22 is an illustrative view of area corresponding to two acoustic wave devices in a substrate assembly used for manufacturing a modification of the acoustic wave device in the first embodiment based on the present disclosure.

FIG. 23 is an illustrative view of a first step in a manufacturing method for obtaining a module in a third embodiment based on the present disclosure.

FIG. 24 is an illustrative view of a second step in the manufacturing method for obtaining the module in the third embodiment based on the present disclosure.

FIG. 25 is a cross-sectional view of the module in the third embodiment based on the present disclosure.

FIG. 26 is a cross-sectional view of a modification of the module in the third embodiment based on the present disclosure.

FIG. 27 is a perspective plan view of a module in a fourth embodiment based on the present disclosure.

FIG. 28 is a plan view of a resonator and the vicinity thereof in a surface acoustic wave device.

FIG. 29 is a cross-sectional view along the line XXIX-XXIX in FIG. 28.

FIG. 30 is a plan view of a resonator and the vicinity thereof in a bulk acoustic wave device.

FIG. 31 is a cross-sectional view along the line XXXI-XXXI in FIG. 30.

FIG. 32 is a circuit diagram of a ladder circuit including a plurality of resonators.

### DETAILED DESCRIPTION OF THE DISCLOSURE

A dimensional ratio shown in the drawings does not necessarily faithfully represent an actual dimensional ratio and a dimensional ratio may be exaggerated for the sake of convenience of description. A concept up or upper or down or lower mentioned in the description below does not mean absolute up or upper or down or lower but may mean relative up or upper or down or lower in terms of a shown position.

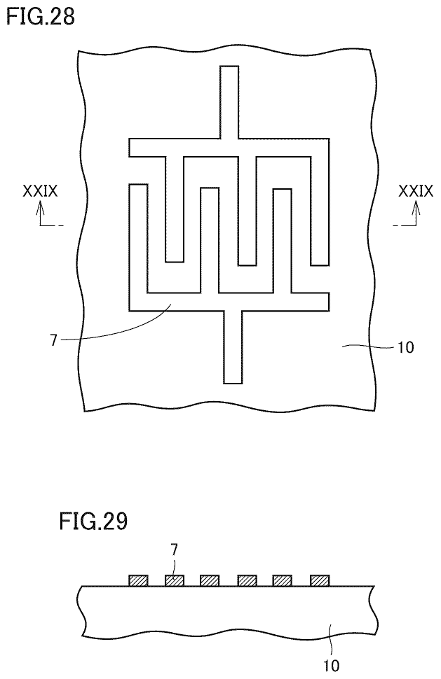

An application of the present disclosure is not limited to a surface acoustic wave device but the present disclosure may be applied, for example, to a bulk acoustic wave device. A structure of a resonator in these acoustic wave devices will be described with reference to FIGS. 28 to 31.

Initially, FIG. 28 shows a plan view of a resonator and the vicinity thereof in a surface acoustic wave device. FIG. 29 shows a cross-sectional view along the line XXIX-XXIX in FIG. 28. In the surface acoustic wave device, a base member 10 for forming a die is formed of a piezoelectric material. The resonator is configured by formation of an IDT electrode 7 at a surface of base member 10.

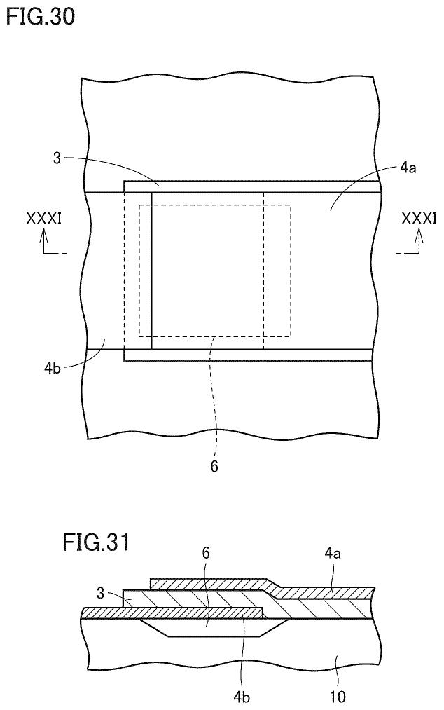

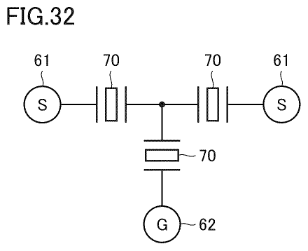

FIG. 30, on the other hand, shows a plan view of a resonator and the vicinity thereof in a bulk acoustic wave device. FIG. 31 shows a cross-sectional view along the line XXXI-XXXI in FIG. 30. In the bulk acoustic wave device, the material for base member 10 for forming a die is not limited to a piezoelectric body. A cavity 6 is provided in the surface of base member 10. The resonator is arranged above cavity 6. The resonator here has such a structure that a piezoelectric membrane 3 lies between electrodes 4a and 4b. At least a part of electrode 4a and at least a part of electrode 4b are opposed to each other with piezoelectric membrane 3 being interposed. Electrode 4a and electrode 4b are not directly electrically connected to each other.

The present disclosure does not relate to the structure of the resonator itself but provides a structure that electrically connects a ground pad wire drawn from the resonator and a first shield film that covers a side surface of a die to each other. Therefore, the present disclosure is applicable regardless of a difference in structure of the resonator.

### First Embodiment

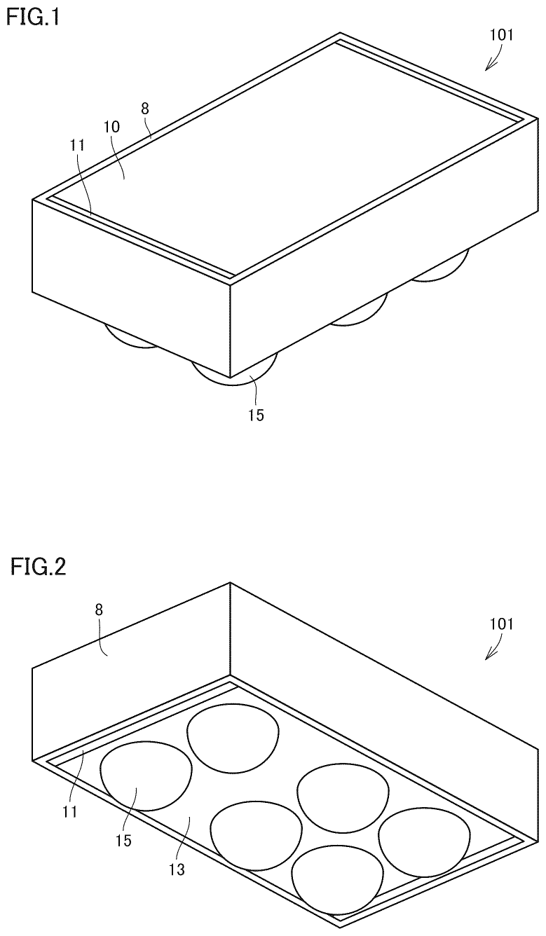

An acoustic wave device 101 in a first embodiment based on the present disclosure will be described with reference to FIGS. 1 to 6. Acoustic wave device 101 shown here is a surface acoustic wave device. This is merely by way of example, and the present disclosure is applicable also to an acoustic wave device other than the surface acoustic wave device. The present disclosure is applicable, for example, to a bulk acoustic wave device.

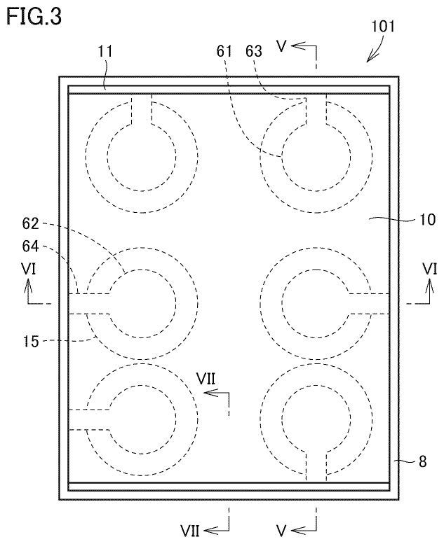

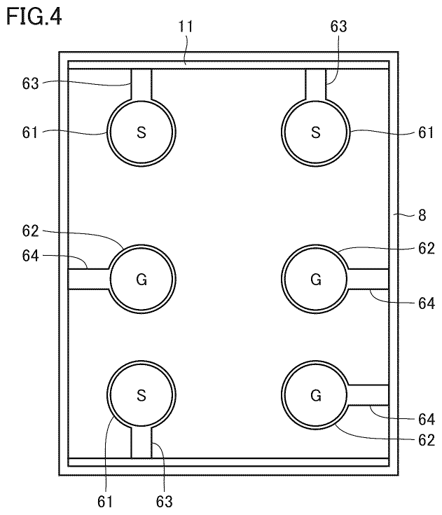

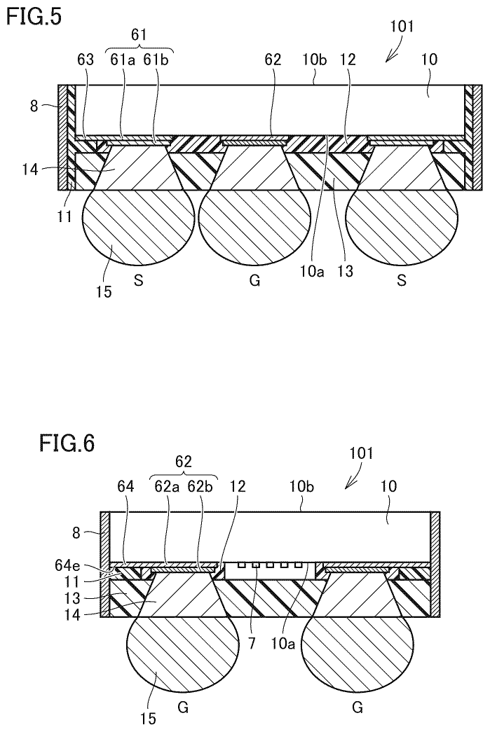

FIG. 1 shows acoustic wave device 101 viewed from diagonally above. An upper surface of base member 10 is exposed at an upper surface of acoustic wave device 101. A first shield film 8 is arranged on a side surface of acoustic wave device 101. FIG. 2 shows acoustic wave device 101 viewed from diagonally below. A plurality of bumps 15 are arranged on a lower surface of acoustic wave device 101. FIG. 3 shows a plan view of acoustic wave device 101. FIG. 3 shows with a dashed line, a component arranged behind base member 10. FIG. 4 shows acoustic wave device 101 viewed from below, with bumps 15 and a cover layer 13 having been removed therefrom. FIG. 4 shows characters “S” and “G” for indication of pad electrodes for the sake of convenience of description. FIG. 5 shows a cross-sectional view along the line V-V in FIG. 3. FIG. 6 shows a cross-sectional view along the line VI-VI in FIG. 3.

Acoustic wave device 101 includes base member 10 and IDT electrode 7 as the resonator. Base member 10 is a member formed of a piezoelectric material. Base member 10 is provided with a first surface 10a and a second surface 10b that define front and rear surfaces. Base member 10 is provided with a plurality of side surfaces that connect first surface 10a and second surface 10b to each other. IDT electrode 7 is arranged at first surface 10a. Though single IDT electrode 7 may be arranged at first surface 10a, a plurality of IDT electrodes 7 may be arranged at first surface 10a. One IDT electrode 7 implements one resonator. In an example where a plurality of resonators are arranged, the plurality of resonators are connected to one another through wires. In the example where the plurality of resonators are arranged, they may configure, for example, a ladder circuit as shown in FIG. 32. This ladder circuit includes three resonators 70, two signal pads 61, and one ground pad 62 by way of example.

As shown in FIGS. 3 to 6, acoustic wave device 101 further includes signal pad 61 and ground pad 62. Signal pad 61 and ground pad 62 are arranged at first surface 10a. Acoustic wave device 101 further includes a signal pad wire 63 that extends to connect signal pad 61 and an end of first surface 10a to each other at first surface 10a and a ground pad wire 64 that extends to connect ground pad 62 and an end of first surface 10a to each other at first surface 10a. Acoustic wave device 101 further includes a support layer 12, cover layer 13, a plurality of conductor vias 14, and first shield film 8. As shown in FIG. 6, support layer 12 is arranged at first surface 10a to surround IDT electrode 7. There may be a plurality of areas surrounded by support layer 12 on first surface 10a. Inside one area surrounded by support layer 12, only a single IDT electrode 7 may be arranged or a plurality of IDT electrodes 7 may be arranged.

Cover layer 13 is connected to first surface 10a with support layer 12 being interposed and covers IDT electrode 7. As shown in FIGS. 5 and 6, the plurality of conductor vias 14 are electrically connected to signal pad 61 and ground pad 62, pass through support layer 12 and cover layer 13, and are exposed at a surface of cover layer 13 opposite to base member 10. First shield film 8 covers a plurality of side surfaces of base member 10. Ground pad wire 64 is electrically connected to first shield film 8 at the end of first surface 10a.

Since an example where acoustic wave device 101 is the surface acoustic wave device is described here, base member 10 is formed of a piezoelectric material. In an example where acoustic wave device 101 is a bulk acoustic wave device, however, the material for base member 10 does not have to be the piezoelectric material. In the example where acoustic wave device 101 is the bulk acoustic wave device, base member 10 may be composed, for example, of a material such as silicon. In the example where acoustic wave device 101 is the bulk acoustic wave device, the resonator may be such a resonator that a structure in which a piezoelectric membrane lies between two electrodes is arranged above a cavity in the base member as shown in FIGS. 30 and 31, instead of the structure where IDT electrode 7 is arranged on the surface of the base member.

As shown in FIG. 5, signal pad 61 includes a signal pad first layer 61a and a signal pad second layer 61b. Signal pad wire 63 extends from signal pad 61. Signal pad wire 63 and signal pad first layer 61a may integrally be formed. Signal pad wire 63 reaches the end of first surface 10a. As shown in FIG. 5, in this cross section, a first insulating film 11 is interposed between first shield film 8 and base member 10 and between first shield film 8 and cover layer 13. An end of signal pad wire 63 is covered with first insulating film 11. Signal pad wire 63 is not in contact with first shield film 8.

As shown in FIG. 6, ground pad 62 incudes a ground pad first layer 62a and a ground pad second layer 62b. Ground pad wire 64 extends from ground pad 62. Ground pad wire 64 and ground pad first layer 62a may integrally be formed. Ground pad wire 64 reaches the end of first surface 10a. As shown in FIG. 6, in this cross section, first insulating film 11 is not interposed between first shield film 8 and base member 10 and not interposed between first shield film 8 and cover layer 13 either. An end of ground pad wire 64 is a portion not covered with first insulating film 11, that is, an end exposed portion 64e. End exposed portion 64e is in contact with first shield film 8.

In acoustic wave device 101 in the present embodiment, ground pad wire 64 and first shield film 8 that covers the side surface are electrically connected to each other. Therefore, acoustic wave device 101 can correctly perform operation as the acoustic wave device and internal noise interference can be suppressed.

As shown in the present embodiment, acoustic wave device 101 preferably includes first insulating film 11 that covers at least one of the plurality of side surfaces while the first insulating film is covered with first shield film 8. As first insulating film 11 covers signal pad wire 63 at a location where signal pad wire 63 reaches the end of first surface 10a, first insulating film 11 preferably electrically isolates first shield film 8 and signal pad wire 63 from each other. Preferably, ground pad wire 64 includes end exposed portion 64e not covered with first insulating film 11 in the vicinity of the end of first surface 10a, and first shield film 8 and the ground pad wire are electrically connected to each other through end exposed portion 64e. By adopting this configuration, while ground pad wire 64 and first shield film 8 that covers the side surface are electrically connected to each other, a state in which signal pad wire 63 and first shield film 8 that covers the side surface are electrically isolated from each other can be realized. Therefore, the structure can be such that first shield film 8 covers the side surface also at the side surface where signal pad wire 63 reaches the end of first surface 10a.

First insulating film 11 is preferably formed of insulating resin. By adopting this configuration, signal pad wire 63 and first shield film 8 can sufficiently be insulated from each other. First insulating film 11 may be formed by pouring a paste of insulating resin and then solidifying the same.

FIG. 7 shows a part of the cross section of acoustic wave device 101 as being enlarged. Though FIG. 5 shows the cross section at a position where signal pad wire 63 is present, FIG. 7 shows a cross section at a position where signal pad wire 63 is absent. FIG. 7 corresponds to the cross section of a portion seen at the left end in FIG. 5, at a position displaced in a front-rear direction of the sheet plane in FIG. 5.

FIG. 8 shows a Z portion in FIG. 7, as being further enlarged. An intimate contact layer 17 is interposed between first insulating film 11 and base member 10. Intimate contact layer 17 is preferably interposed in this manner. By adopting this configuration, intimate contact between first insulating film 11 and base member 10 improves and reliability of acoustic wave device 101 is enhanced. Furthermore, as illustrated in FIG. 8, intimate contact layer 17 may be interposed also between cover layer 13 and base member 10.

### (Power Feed Line)

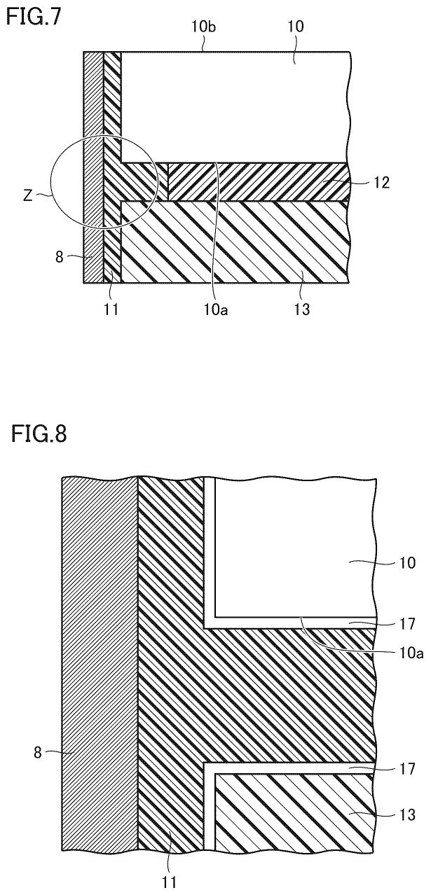

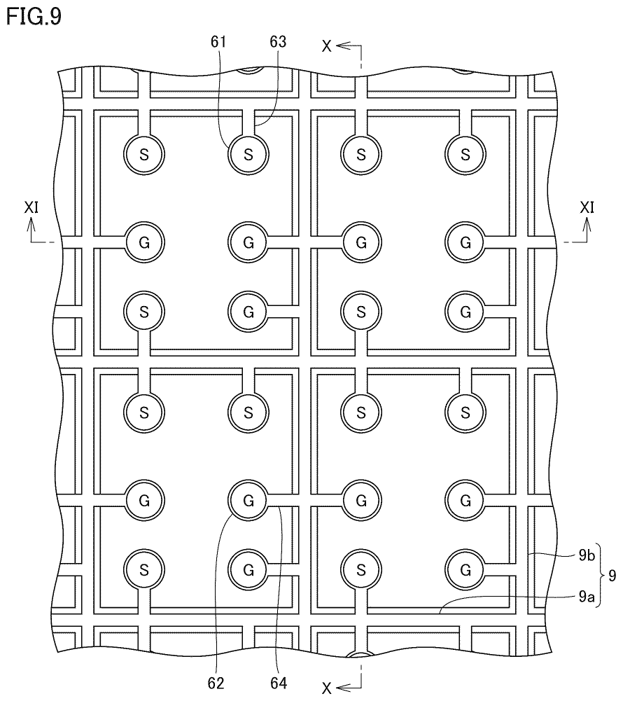

A power feed line that extends from each pad is used for plating growth of the plurality of conductor vias 14. In manufacturing of acoustic wave device 101, a large substrate assembly is used to collectively manufacture a plurality of acoustic wave devices 101. FIG. 9 shows areas corresponding to four acoustic wave devices 101 as being taken out, four acoustic wave devices 101 being aligned adjacently in the substrate assembly. In FIG. 9, the areas corresponding to four acoustic wave devices 101 are arranged in 2×2. Power feed lines 9 are arranged in grids to pass through a boundary line between areas corresponding to acoustic wave devices 101. Power feed line 9 includes a first power feed portion 9a and a second power feed portion 9b. In the example shown here, first power feed portion 9a extends in a lateral direction in the figure and second power feed portion 9b extends in an upward-downward direction in the figure. FIG. 9 shows a character “S” for signal pad 61 and a character “G” for ground pad 62 for the sake of convenience of description. Signal pad 61 is connected to first power feed portion 9a through signal pad wire 63. Ground pad 62 is connected to second power feed portion 9b through ground pad wire 64. Signal pad 61 and ground pad 62 are thus connected to portions of power feed line 9 that extend in different directions. Power feed line 9 is subsequently removed by grooving. As power feed line 9 is removed, signal pad wire 63 and ground pad wire 64 lose components to which they are connected, and are isolated.

### Second Embodiment

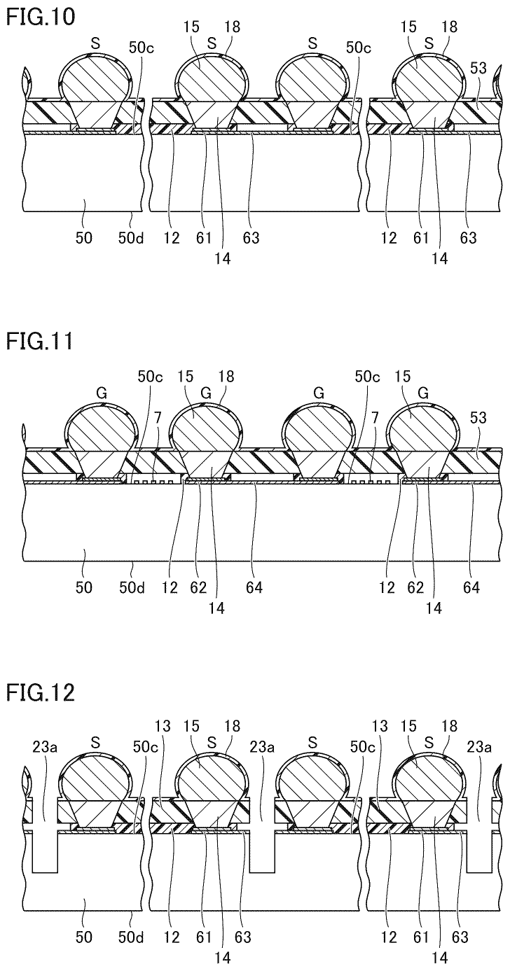

A method of manufacturing an acoustic wave device in a second embodiment based on the present disclosure will be described with reference to FIGS. 10 to 21. FIG. 10 shows a cross section at a location where signal pad wire 63 is drawn to the end of first surface 10a and FIG. 11 shows a cross section at a location where ground pad wire 64 is drawn to the end of first surface 10a.

This method of manufacturing the acoustic wave device is a manufacturing method for obtaining any acoustic wave device described above. This method of manufacturing the acoustic wave device includes a step of preparing a component provided with a third surface 50c and a fourth surface 50d that define front and rear surfaces, where a cover layer assembly 53 is connected to third surface 50c of a substrate assembly 50 with support layer 12 being interposed, substrate assembly 50 being provided with a plurality of sections arranged in matrix as corresponding to a plurality of acoustic wave devices. Substrate assembly 50 is a member in a form of a plate which is formed of a piezoelectric material. This method of manufacturing the acoustic wave device further includes a step of forming a photoresist film 18 to cover a surface of cover layer assembly 53 on a side distant from substrate assembly 50. FIGS. 10 and 11 show a state after the steps so far were performed. A surface of bump 15 and an upper surface of cover layer assembly 53 are covered with photoresist film 18.

Substrate assembly 50 will be base member 10 by being cut into individual product-size substrates. Cover layer assembly 53 will be cover layer 13 by being cut into individual product-size cover layers.

This method of manufacturing the acoustic wave device further includes a step of providing a groove 23a having a first width by half-cut of the surface of cover layer assembly 53 on the side distant from substrate assembly 50 with a first dicer along a boundary line that extends in a first direction of the plurality of sections. The “first direction” refers to the lateral direction in FIG. 9. As shown in FIG. 12, groove 23a having the first width is provided only along the boundary line that extends in the first direction, and the boundary line that extends in a direction different therefrom does not change from the state shown in FIG. 11. In FIG. 12, cover layer assembly 53 has already become a plurality of cover layers 13 by being cut.

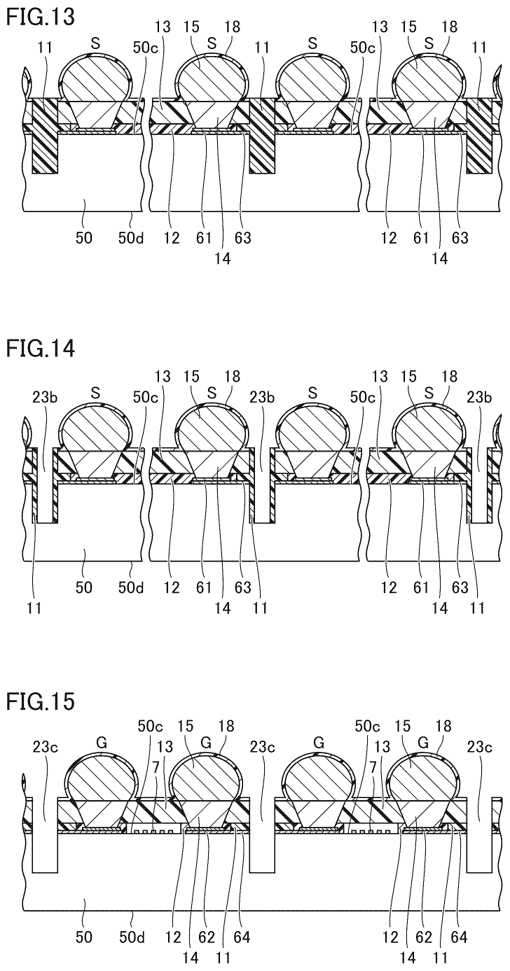

This method of manufacturing the acoustic wave device further includes a step of filling groove 23a with insulating resin as shown in FIG. 13. As a result of filling groove 23a, a portion that has been groove 23a is now filled with first insulating film 11.

This method of manufacturing the acoustic wave device further includes a step of providing grooves 23b and 23c having a second width narrower than the first width by half-cut with a second dicer smaller in thickness than the first dicer, along the boundary line that extends in the first direction and a boundary line that extends in a second direction different from the first direction, as shown in FIGS. 14 and 15. Groove 23b is provided along the boundary line that extends in the first direction (see FIG. 14). Groove 23c is provided along the boundary line that extends in the second direction (see FIG. 15). Though groove 23b and groove 23c appear to be different from each other in width in the figures, groove 23b and groove 23c are actually equal to each other in width. As shown in FIG. 14, groove 23b is narrower than groove 23a and hence first insulating film 11 remains like a wall on an inner surface of groove 23b. Much first insulating film 11 thus remains along the boundary line that extends in the first direction. Though groove 23c is provided as shown in FIG. 15 along the boundary line that extends in the second direction, on the other hand, most of an inner surface of groove 23c is not covered with first insulating film 11.

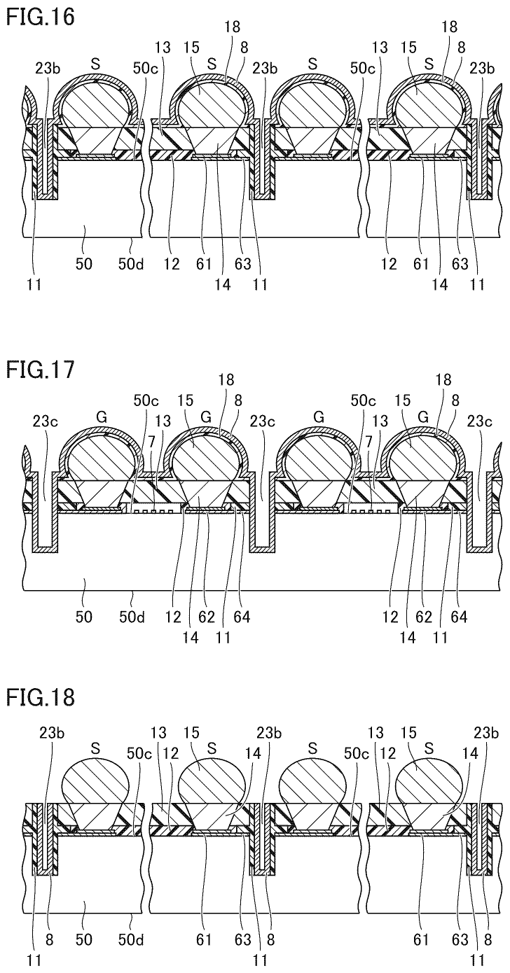

This method of manufacturing the acoustic wave device further includes a step of forming a conductive material layer to cover the inner surfaces of grooves 23b and 23c having the second width as shown in FIGS. 16 and 17. The conductive material layer can be formed by applying a conductive paint. Alternatively, the conductive material layer can be formed by such a method as plating or sputtering. By performing this step, the inner surfaces of grooves 23b and 23c are covered with the conductive material layer. Furthermore, the surface of bump 15 and the upper surface of cover layer assembly 53 are also covered with the conductive material layer. FIGS. 16 and 17 show the conductive material layer as first shield film 8.

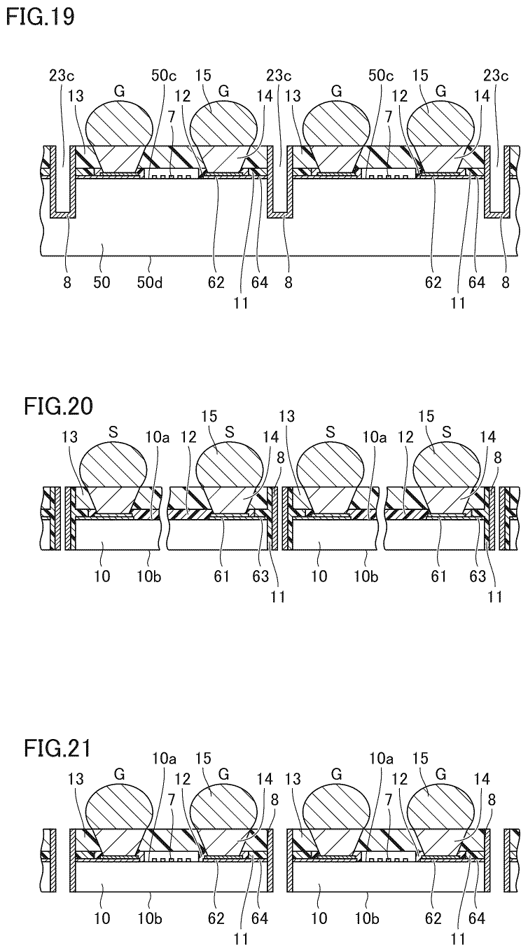

This method of manufacturing the acoustic wave device further includes a step of removing photoresist film 18 as shown in FIGS. 18 and 19. By removing photoresist film 18, a portion of the conductive material layer that has been formed as being overlaid on photoresist film 18 is removed.

This method of manufacturing the acoustic wave device further includes a step of dividing substrate assembly 50 into individual product-size substrates, by grinding fourth surface 50d as shown in FIGS. 20 and 21. As a result of grinding, grooves 23b and 23c have no bottom, and substrate assembly 50 has already been divided into individual product-size substrates. By grinding, a thickness of a portion that has been substrate assembly 50 becomes smaller, and each divided substrate serves as base member 10. A plurality of acoustic wave devices 101 can thus be obtained.

According to the present embodiment, the acoustic wave devices can efficiently be made. In the first and second embodiments, as shown in FIG. 9, signal pad wire 63 is each described as being connected to first power feed portion 9a of power feed line 9 that extends in the first direction, that is, a side that extends in the lateral direction in the figure, and ground pad wire 64 is each described as being connected to second power feed portion 9b of power feed line 9 that extends in the second direction, that is, a side that extends in the upward-downward direction in the figure. Depending on a type, that is, whether the wire is signal pad wire 63 or ground pad wire 64, to which power feed portion it is connected is in conformity with a certain rule. In a modification, however, differently from this rule, ground pad wire 64 may be connected to a side, for example, as shown in FIG. 22.

### Third Embodiment

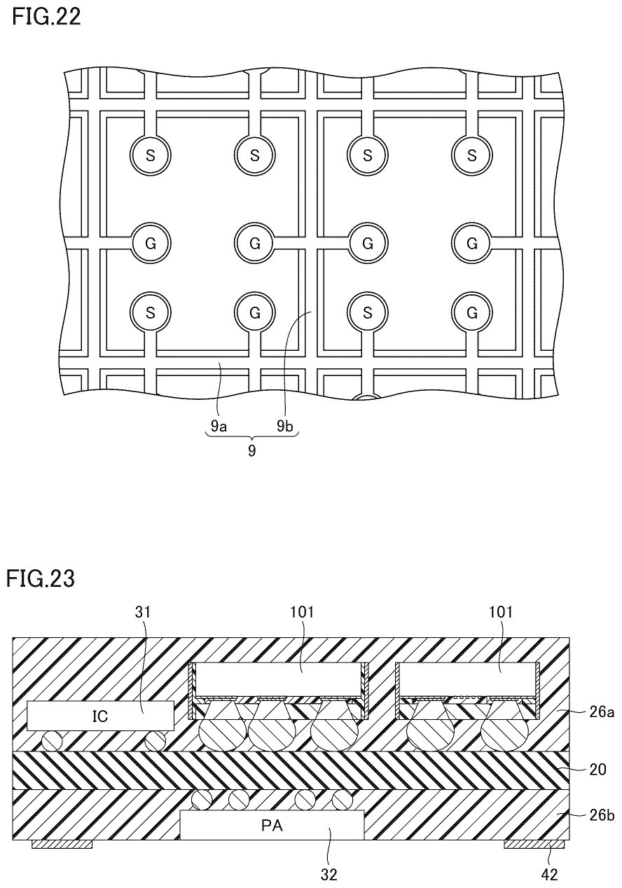

A module in a third embodiment based on the present disclosure will be described with reference to FIGS. 23 to 25. A manufacturing method for obtaining this module will be described first. Though the example in which the acoustic wave device is the surface acoustic wave device will be described, the acoustic wave device is not limited to the surface acoustic wave device but another type of acoustic wave device may be applicable.

Initially, as shown in FIG. 23, a necessary number of acoustic wave devices 101 are mounted on an upper surface of a module substrate 20 and sealed with sealing resin 26a. Other electronic components may also be mounted on the upper surface of module substrate 20. In FIG. 23, an integrated circuit (IC) 31 is mounted by way of example. IC 31 is also sealed with sealing resin 26a.

An electronic component may be mounted also on a lower surface of module substrate 20. In FIG. 23, a power amplifier (PA) 32 is mounted by way of example. PA 32 and the lower surface of module substrate 20 are sealed with sealing resin 26b. An external terminal 42 is arranged on a lower surface of sealing resin 26b. In the example shown here, a lower surface of PA 32 is exposed at the lower surface of sealing resin 26b. Though an example of a double-sided mount structure is described, this is merely by way of example. There may be no electronic component mounted on the lower surface of module substrate 20.

An upper surface of this structure is then ground. A part of acoustic wave device 101 mounted on the upper surface of module substrate 20 is thus also ground away as shown in FIG. 24. Each acoustic wave device 101 is made smaller in thickness by removal of a part of base member 10. As shown in FIG. 24, an upper surface of acoustic wave device 101 and an upper surface of sealing resin 26a are flush with each other. An upper end of first shield film 8 provided in acoustic wave device 101 is also exposed.

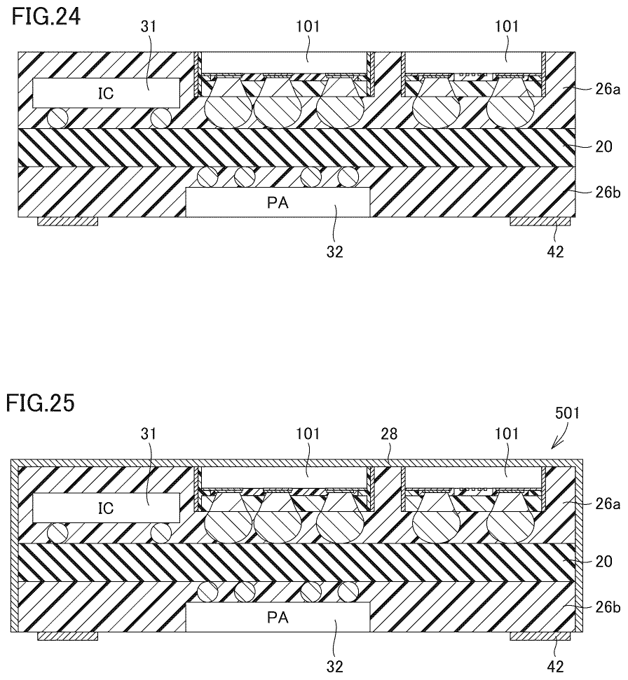

A metallic film is formed on the upper surface and a side surface of this structure by sputtering. A second shield film 28 is thus formed as shown in FIG. 25. Second shield film 28 covers an upper surface and a side surface of sealing resin 26a. The upper surface of acoustic wave device 101 exposed through sealing resin 26a is also covered with second shield film 28. A side surface of module substrate 20 and a side surface of sealing resin 26b are also covered with second shield film 28. A module 501 is thus obtained as shown in FIG. 25.

A configuration of module 501 is again described. Module 501 includes any acoustic wave device 101 described so far and module substrate 20 provided with the mount surface. Acoustic wave device 101 is mounted on the mount surface with bumps 15 being interposed, bumps 15 being connected to locations in cover layer 13 where the plurality of conductor vias 14 are exposed. The side surface and the mount surface of acoustic wave device 101 are covered with sealing resin 26a. The side surface and the upper surface of sealing resin 26a and the upper surface of the acoustic wave device are covered with second shield film 28. First shield film 8 and second shield film 28 are electrically connected to each other at an upper end of at least one of the plurality of side surfaces of base member 10.

Module 501 in the present embodiment includes acoustic wave device 101. Therefore, inside acoustic wave device 101, ground pad wire 64 and first shield film 8 that covers the side surface are electrically connected to each other. Therefore, the operation as the acoustic wave device can correctly be performed and internal noise interference can be suppressed.

A configuration like a module 502 shown in FIG. 26 may be applicable. Module 502 is in a one-sided mount structure. What is mounted on the upper surface of module substrate 20 is sealed with sealing resin 26, together with the upper surface of module substrate 20. In module 502, acoustic wave device 101 is arranged at the center of the upper surface of module substrate 20, PA 32 is mounted on the left side in the figure, and a low noise amplifier (LNA) 33 and other components 34 and 35 are mounted on the right side in the figure. External terminal 42 is arranged on the lower surface of module substrate 20. Since acoustic wave device 101 includes first shield film 8 to cover the side surface of base member 10, acoustic wave device 101 is arranged between PA 32, and LNA 33 and other components 34 and 35. A degree of electromagnetic waves emitted from PA 32 reaching LNA 33 and other components 34 and 35 can thus be lowered.

### Fourth Embodiment

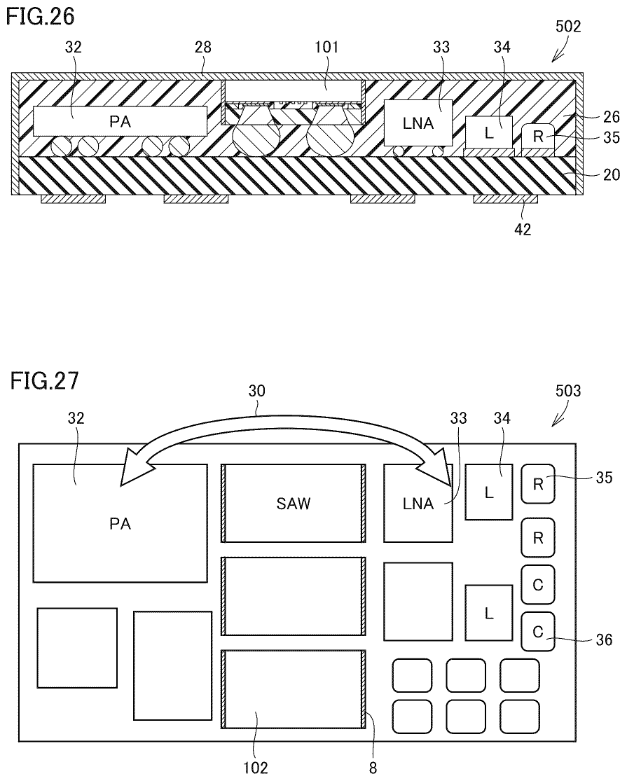

A module in a fourth embodiment based on the present disclosure will be described with reference to FIG. 27. FIG. 27 shows a perspective plan view of a module 503 in the present embodiment. Module 503 may include or may not include second shield film 28. Module 503 will be described as not including second shield film 28. FIG. 27 shows a portion which is basically invisible by being covered with sealing resin. Module 503 includes PA 32, a plurality of acoustic wave devices 102, LNA 33, and other components 34, 35, and 36. Each of the plurality of acoustic wave devices 102 is provided with four side surfaces, and at least two side surfaces opposed to each other among the four side surfaces are provided with first shield film 8. Acoustic wave device 102 will be described as including first shield film 8 only on two side surfaces opposed to each other.

Module 503 includes the plurality of acoustic wave devices 102 and module substrate 20 provided with the mount surface. Each of the plurality of acoustic wave devices 102 is the acoustic wave device in any configuration described so far. Each of the plurality of acoustic wave devices 102 is mounted on the mount surface with bumps 15 being interposed, the bumps being connected to locations in cover layer 13 where the plurality of conductor vias 14 are exposed. The side surface and the mount surface of the acoustic wave device are covered with sealing resin 26. An interfering component and an interfered component are mounted on the mount surface. PA 32 falls under the interfering component and LNA 33 and components 34, 35, and 36 fall under the interfered component. The plurality of acoustic wave devices 102 are arranged to form a row that separates the interfering component and the interfered component from each other. Each of the plurality of acoustic wave devices 102 is provided with first shield film 8 on a side surface opposed to at least one of the interfering component and the interfered component.

In the present embodiment, the plurality of acoustic wave devices 102 are arranged to form the row that separates the interfering component and the interfered component from each other and each of the plurality of acoustic wave devices 102 is provided with first shield film 8 on the side surface opposed to at least one of the interfering component and the interfered component. Therefore, aligned first shield films 8 like a wall can cut off electromagnetic waves 30 that come and go between the interfering component and the interfered component. Consequently, since the interfered component is hardly affected by electromagnetic waves from the interfering component, module 503 can be higher in reliability. Though FIG. 27 shows electromagnetic waves 30 with a double-headed arrow, they are virtual and such electromagnetic waves 30 are actually substantially cut off by aligned first shield films 8.

A plurality of embodiments of the embodiments above may be adopted as being combined as appropriate. The embodiments disclosed herein are illustrative and non-restrictive in every respect. The scope of the present disclosure is defined by the terms of the claims and is intended to include any modifications within the scope and meaning equivalent to the terms of the claims.

### (Additional Aspects)

(Additional Aspect 1) An acoustic wave device includes a base member provided with a first surface and a second surface and a plurality of side surfaces, the first surface and the second surface defining front and rear surfaces, the plurality of side surfaces connecting the first surface and the second surface to each other, a resonator arranged at the first surface, a signal pad and a ground pad arranged at the first surface, a signal pad wire that extends to connect the signal pad and an end of the first surface to each other at the first surface, a ground pad wire that extends to connect the ground pad and an end of the first surface to each other at the first surface, a support layer arranged at the first surface to surround the resonator, a cover layer connected to the first surface with the support layer being interposed, the cover layer covering the resonator, a plurality of conductor vias electrically connected to the signal pad and the ground pad, the plurality of conductor vias passing through the support layer and the cover layer, the plurality of conductor vias being exposed at a surface of the cover layer opposite to the base member, and a first shield film that covers the plurality of side surfaces, and the ground pad wire is electrically connected to the first shield film at the end of the first surface.

(Additional Aspect 2) The acoustic wave device described in Additional Aspect 1 includes a first insulating film that covers at least one of the plurality of side surfaces while the first insulating film is covered with the first shield film, at a location where the signal pad wire reaches the end of the first surface, the first insulating film covers the signal pad wire so that the first insulating film electrically isolates the first shield film and the signal pad wire from each other, and the ground pad wire includes in the vicinity of the end of the first surface, an end exposed portion not covered with the first insulating film, and the first shield film and the ground pad wire are electrically connected to each other through the end exposed portion.

(Additional Aspect 3) In the acoustic wave device described in Additional Aspect 2, the first insulating film is formed of insulating resin.

(Additional Aspect 4) In the acoustic wave device described in Additional Aspect 2 or 3, an intimate contact layer is interposed between the first insulating film and the base member.

(Additional Aspect 5) A manufacturing method for obtaining the acoustic wave device described in any one of Additional Aspects 1 to 4 includes preparing a component provided with a third surface and a fourth surface that define front and rear surfaces, in the component, a cover layer assembly being connected to the third surface of a substrate assembly with the support layer being interposed, the substrate assembly including a plurality of sections arranged in matrix as corresponding to a plurality of acoustic wave devices, forming a photoresist film to cover a surface of the cover layer assembly on a side distant from the substrate assembly, providing a groove having a first width by half-cut of the surface of the cover layer assembly on the side distant from the substrate assembly with a first dicer along a boundary line that extends in a first direction of the plurality of sections, filling the groove with insulating resin, providing a groove having a second width narrower than the first width by half-cut with a second dicer smaller in thickness than the first dicer, along the boundary line that extends in the first direction and a boundary line that extends in a second direction different from the first direction, forming a conductive material layer to cover an inner surface of the groove having the second width, removing the photoresist film, and dividing the substrate assembly into individual product-size substrates by grinding the fourth surface.

(Additional Aspect 6) A module includes the acoustic wave device described in any one of Additional Aspects 1 to 4, and a module substrate provided with a mount surface, the acoustic wave device is mounted on the mount surface with bumps being interposed, the bumps being connected to locations in the cover layer where the plurality of conductor vias are exposed, a side surface and the mount surface of the acoustic wave device being covered with sealing resin, a side surface and an upper surface of the sealing resin and an upper surface of the acoustic wave device are covered with a second shield film, and the first shield film and the second shield film are electrically connected to each other at an upper end of at least one of the plurality of side surfaces of the base member.

(Additional Aspect 7) A module includes a plurality of acoustic wave devices, and a module substrate provided with a mount surface, each of the plurality of acoustic wave devices is the acoustic wave device described in any one of Additional Aspects 1 to 4, each of the plurality of acoustic wave devices is mounted on the mount surface with bumps being interposed, the bumps being connected to locations in the cover layer where the plurality of conductor vias are exposed, a side surface and the mount surface of the acoustic wave device being covered with sealing resin, an interfering component and an interfered component are mounted on the mount surface, the plurality of acoustic wave devices are arranged to form a row that separates the interfering component and the interfered component from each other, and each of the plurality of acoustic wave devices is provided with the first shield film on a side surface opposed to at least one of the interfering component and the interfered component.

3 piezoelectric membrane; 4a, 4b electrode; 6 cavity; 7 IDT electrode; 8 first shield film; 9 power feed line; 9a first power feed portion (of power feed line); 9b second power feed portion (of power feed line); 10 base member; 10a first surface; 10b second surface; 11 first insulating film; 12 support layer; 13 cover layer; 14 conductor via; 15 bump; 17 intimate contact layer; 18 photoresist film; 20 module substrate; 22 base member; 23a groove (having first width); 23b, 23c groove (having second width); 26, 26a, 26b sealing resin; 28 second shield film; 31 IC; 32 PA; 33 LNA; 34, 35, 36 component; 42 external terminal; 50 substrate assembly; 50c third surface; 50d fourth surface; 53 cover layer assembly; 61 signal pad; 62 ground pad; 61a signal pad first layer; 61b signal pad second layer; 62a ground pad first layer; 62b ground pad second layer; 63 signal pad wire; 64 ground pad wire; 64e end exposed portion; 70 resonator; 101, 102 acoustic wave device; 501, 502, 503 module.

1. An acoustic wave device comprising:
a base member provided with a first surface and a second surface and a plurality of side surfaces, the first surface and the second surface defining front and rear surfaces, respectively, the plurality of side surfaces connecting the first surface and the second surface to each other;
a resonator arranged at the first surface;
a signal pad and a ground pad arranged at the first surface;
a signal pad wire extending to connect the signal pad and an end of the first surface to each other at the first surface;
a ground pad wire extending to connect the ground pad and the end of the first surface to each other at the first surface;
a support layer arranged at the first surface to surround the resonator;
a cover layer connected to the first surface with the support layer being interposed, the cover layer covering the resonator;
a plurality of conductor vias electrically connected to the signal pad and the ground pad, the plurality of conductor vias passing through the support layer and the cover layer, the plurality of conductor vias being exposed at a surface of the cover layer opposite to the base member; and
a first shield film covering the plurality of side surfaces, wherein
the ground pad wire is electrically connected to the first shield film at the end of the first surface.

2. The acoustic wave device according to claim 1, further comprising a first insulating film covering at least one of the plurality of side surfaces while the first insulating film is covered with the first shield film, wherein
at a location where the signal pad wire reaches the end of the first surface, the first insulating film covers the signal pad wire so that the first insulating film electrically isolates the first shield film and the signal pad wire from each other, and
the ground pad wire includes, in a vicinity of the end of the first surface, an end exposed portion not covered with the first insulating film, and the first shield film and the ground pad wire are electrically connected to each other through the end exposed portion.

3. The acoustic wave device according to claim 2, wherein
the first insulating film comprises an insulating resin.

4. The acoustic wave device according to claim 2, wherein
an intimate contact layer is interposed between the first insulating film and the base member.

5. A manufacturing method for obtaining the acoustic wave device according to claim 1, the manufacturing method comprising:
preparing a component provided with a third surface and a fourth surface, the third surface and the fourth surface defining front and rear surfaces, respectively, in the component, a cover layer assembly being connected to the third surface of a substrate assembly with the support layer being interposed, the substrate assembly including a plurality of sections arranged in matrix as corresponding to a plurality of acoustic wave devices;
forming a photoresist film to cover a surface of the cover layer assembly on a side distant from the substrate assembly;
providing a groove having a first width by half-cut of the surface of the cover layer assembly on the side distant from the substrate assembly with a first dicer along a first boundary line extending in a first direction of the plurality of sections;
filling the groove with an insulating resin;
providing a groove having a second width narrower than the first width by half-cut with a second dicer thinner in thickness than the first dicer, along the first boundary line extending in the first direction and a second boundary line extending in a second direction different from the first direction;
forming a conductive material layer to cover an inner surface of the groove having the second width;
removing the photoresist film; and
dividing the substrate assembly into individual product-size substrates by grinding the fourth surface.

6. A module comprising:
the acoustic wave device according to claim 1; and
a module substrate provided with a mount surface, wherein
the acoustic wave device is mounted on the mount surface with bumps being interposed, the bumps being connected to locations in the cover layer where the plurality of conductor vias are exposed, a side surface and the mount surface of the acoustic wave device being covered with a sealing resin,
a side surface and an upper surface of the sealing resin and an upper surface of the acoustic wave device are covered with a second shield film, and
the first shield film and the second shield film are electrically connected to each other at an upper end of at least one of the plurality of side surfaces of the base member.

7. A module comprising:
a plurality of acoustic wave devices; and
a module substrate provided with a mount surface, wherein
each of the plurality of acoustic wave devices is the acoustic wave device according to claim 1,
each of the plurality of acoustic wave devices is mounted on the mount surface with bumps being interposed, the bumps being connected to locations in the cover layer where the plurality of conductor vias are exposed, a side surface and the mount surface of the acoustic wave device being covered with a sealing resin,
an interfering component and an interfered component are mounted on the mount surface,
the plurality of acoustic wave devices are arranged to form a row separating the interfering component and the interfered component from each other, and
each of the plurality of acoustic wave devices is provided with the first shield film on a side surface opposed to at least one of the interfering component and the interfered component.

8. The acoustic wave device according to claim 3, wherein
an intimate contact layer is interposed between the first insulating film and the base member.

9. A manufacturing method for obtaining the acoustic wave device according to claim 2, the manufacturing method comprising:
preparing a component provided with a third surface and a fourth surface, the third surface and the fourth surface defining front and rear surfaces, respectively, in the component, a cover layer assembly being connected to the third surface of a substrate assembly with the support layer being interposed, the substrate assembly including a plurality of sections arranged in matrix as corresponding to a plurality of acoustic wave devices;
forming a photoresist film to cover a surface of the cover layer assembly on a side distant from the substrate assembly;
providing a groove having a first width by half-cut of the surface of the cover layer assembly on the side distant from the substrate assembly with a first dicer along a first boundary line extending in a first direction of the plurality of sections;
filling the groove with an insulating resin;
providing a groove having a second width narrower than the first width by half-cut with a second dicer thinner in thickness than the first dicer, along the first boundary line extending in the first direction and a second boundary line extending in a second direction different from the first direction;
forming a conductive material layer to cover an inner surface of the groove having the second width;
removing the photoresist film; and
dividing the substrate assembly into individual product-size substrates by grinding the fourth surface.

10. A manufacturing method for obtaining the acoustic wave device according to claim 3, the manufacturing method comprising:
preparing a component provided with a third surface and a fourth surface, the third surface and the fourth surface defining front and rear surfaces, respectively, in the component, a cover layer assembly being connected to the third surface of a substrate assembly with the support layer being interposed, the substrate assembly including a plurality of sections arranged in matrix as corresponding to a plurality of acoustic wave devices;
forming a photoresist film to cover a surface of the cover layer assembly on a side distant from the substrate assembly;
providing a groove having a first width by half-cut of the surface of the cover layer assembly on the side distant from the substrate assembly with a first dicer along a first boundary line extending in a first direction of the plurality of sections;
filling the groove with an insulating resin;
providing a groove having a second width narrower than the first width by half-cut with a second dicer thinner in thickness than the first dicer, along the first boundary line extending in the first direction and a second boundary line extending in a second direction different from the first direction;
forming a conductive material layer to cover an inner surface of the groove having the second width;
removing the photoresist film; and
dividing the substrate assembly into individual product-size substrates by grinding the fourth surface.

11. A manufacturing method for obtaining the acoustic wave device according to claim 4, the manufacturing method comprising:
preparing a component provided with a third surface and a fourth surface, the third surface and the fourth surface defining front and rear surfaces, respectively, in the component, a cover layer assembly being connected to the third surface of a substrate assembly with the support layer being interposed, the substrate assembly including a plurality of sections arranged in matrix as corresponding to a plurality of acoustic wave devices;
forming a photoresist film to cover a surface of the cover layer assembly on a side distant from the substrate assembly;
providing a groove having a first width by half-cut of the surface of the cover layer assembly on the side distant from the substrate assembly with a first dicer along a first boundary line extending in a first direction of the plurality of sections;
filling the groove with an insulating resin;
providing a groove having a second width narrower than the first width by half-cut with a second dicer thinner in thickness than the first dicer, along the first boundary line extending in the first direction and a second boundary line extending in a second direction different from the first direction;
forming a conductive material layer to cover an inner surface of the groove having the second width;
removing the photoresist film; and
dividing the substrate assembly into individual product-size substrates by grinding the fourth surface.

12. A module comprising:
the acoustic wave device according to claim 2; and
a module substrate provided with a mount surface, wherein
the acoustic wave device is mounted on the mount surface with bumps being interposed, the bumps being connected to locations in the cover layer where the plurality of conductor vias are exposed, a side surface and the mount surface of the acoustic wave device being covered with a sealing resin,
a side surface and an upper surface of the sealing resin and an upper surface of the acoustic wave device are covered with a second shield film, and
the first shield film and the second shield film are electrically connected to each other at an upper end of at least one of the plurality of side surfaces of the base member.

13. A module comprising:
the acoustic wave device according to claim 3; and
a module substrate provided with a mount surface, wherein
the acoustic wave device is mounted on the mount surface with bumps being interposed, the bumps being connected to locations in the cover layer where the plurality of conductor vias are exposed, a side surface and the mount surface of the acoustic wave device being covered with a sealing resin,
a side surface and an upper surface of the sealing resin and an upper surface of the acoustic wave device are covered with a second shield film, and
the first shield film and the second shield film are electrically connected to each other at an upper end of at least one of the plurality of side surfaces of the base member.

14. A module comprising:
the acoustic wave device according to claim 4; and
a module substrate provided with a mount surface, wherein
the acoustic wave device is mounted on the mount surface with bumps being interposed, the bumps being connected to locations in the cover layer where the plurality of conductor vias are exposed, a side surface and the mount surface of the acoustic wave device being covered with a sealing resin,
a side surface and an upper surface of the sealing resin and an upper surface of the acoustic wave device are covered with a second shield film, and
the first shield film and the second shield film are electrically connected to each other at an upper end of at least one of the plurality of side surfaces of the base member.

15. A module comprising:
a plurality of acoustic wave devices; and
a module substrate provided with a mount surface, wherein
each of the plurality of acoustic wave devices is the acoustic wave device according to claim 2,
each of the plurality of acoustic wave devices is mounted on the mount surface with bumps being interposed, the bumps being connected to locations in the cover layer where the plurality of conductor vias are exposed, a side surface and the mount surface of the acoustic wave device being covered with a sealing resin,
an interfering component and an interfered component are mounted on the mount surface,
the plurality of acoustic wave devices are arranged to form a row separating the interfering component and the interfered component from each other, and
each of the plurality of acoustic wave devices is provided with the first shield film on a side surface opposed to at least one of the interfering component and the interfered component.

16. A module comprising:
a plurality of acoustic wave devices; and
a module substrate provided with a mount surface, wherein
each of the plurality of acoustic wave devices is the acoustic wave device according to claim 3,
each of the plurality of acoustic wave devices is mounted on the mount surface with bumps being interposed, the bumps being connected to locations in the cover layer where the plurality of conductor vias are exposed, a side surface and the mount surface of the acoustic wave device being covered with a sealing resin,
an interfering component and an interfered component are mounted on the mount surface,
the plurality of acoustic wave devices are arranged to form a row separating the interfering component and the interfered component from each other, and
each of the plurality of acoustic wave devices is provided with the first shield film on a side surface opposed to at least one of the interfering component and the interfered component.

17. A module comprising:
a plurality of acoustic wave devices; and
a module substrate provided with a mount surface, wherein
each of the plurality of acoustic wave devices is the acoustic wave device according to claim 4,
each of the plurality of acoustic wave devices is mounted on the mount surface with bumps being interposed, the bumps being connected to locations in the cover layer where the plurality of conductor vias are exposed, a side surface and the mount surface of the acoustic wave device being covered with a sealing resin,
an interfering component and an interfered component are mounted on the mount surface,
the plurality of acoustic wave devices are arranged to form a row separating the interfering component and the interfered component from each other, and
each of the plurality of acoustic wave devices is provided with the first shield film on a side surface opposed to at least one of the interfering component and the interfered component.
